(19) United States
(12) Patent Application Publication
(10) Pub. No.: US 2007/0268073 A1
(43) Pub. Date: Nov. 22, 2007

(54) Electronic device

(76) Inventors: Hidefumi Suzaki, Shiga (JP); Hiroyasu Takehara, Osaka (JP); Yorito Ota, Hyogo (JP)

Correspondence Address: MCDERMOTT WILL & EMERY LLP, 600 13TH STREET, N.W., WASHINGTON, DC, 20005-3096, US

(21) Appl. No.: 11/640,390

(22) Filed: Dec. 18, 2006

(30) Foreign Application Priority Data
May 17, 2006 (JP) 2006-138167

(51) Int. Cl. H03F 3/191

(52) U.S. Cl. 330/295; 330/302

(57) ABSTRACT

An electronic device includes: a plurality of RF power amplifiers; and an impedance converting circuit. The RF power amplifiers amplify RF signals having different frequencies. The impedance converting circuit receives RF signals output from output terminals of the respective RF power amplifiers at a plurality of input terminals disposed to face the respective output terminals, and performs impedance conversion.

### BACKGROUND OF THE INVENTION

(1) Field of the Invention

The present invention relates to RF (radio frequency) power amplifiers for amplifying RF signals for communication of transceivers used as compact lightweight thin high-performance mobile equipment such as cellular phones.

(2) Background Art/Disclosure of Related Art

Mobile equipment such as cellular phones includes RF power amplifiers for amplifying a signal in an RF band to a power level high enough for transmission. These RF power amplifiers are required to have low power consumption, be small and be able to be fabricated at low cost. To meet these requirements, High Electron Mobility Transistors (HEMTs) and Heterojunction Bipolar Transistors using compound semiconductor RF devices such as GaAs devices are used as amplification transistors of the RF power amplifiers.

The performance of an RF power amplifier is limited by the frequency and bandwidth. Especially in a linear power amplifier using code-division multiple access (CDMA), the frequency bandwidth satisfying required performance is only about 50 MHz in a 1 GHz band and a fractional bandwidth of only about 5% is secured. For recent mobile phones, to cope with an increase in number of subscribers, addition of frequency bands involved in provision of new service and frequencies/systems allocated to each country, a shift to multiband communication in which a plurality of RF bands are used by one mobile equipment is accelerated. With this shift, RF circuits in the mobile equipment have become complicated, and the number of RF parts for processing different frequency bands increases. In particular, an RF power amplifier with which a fractional bandwidth of only about 5% is secured as described above needs an amplifying circuit for one system associated with each additional frequency band. Accordingly, RF power amplifiers for as many as three systems are mounted in recent mobile equipment. This greatly restricts size reduction of equipment. On the other hand, thickness reduction of RF power amplifiers is strongly needed so as to be mounted on card type mobile equipment or radio cards.

FIG. 9 illustrates an example of a circuit configuration of a conventional RF power amplifier, and specifically a three-stage circuit for amplifying a signal in a frequency band of one system. More specifically, in the RF power amplifier illustrated in FIG. 9, bipolar transistors are used as three transistors 126, 127 and 128 arranged in series. The transistors 126 through 128 are connected to bias circuits 129, 130 and 131 so as to obtain desired collector current from the transistors 126 through 128. An input matching circuit 132 necessary for suppressing reflection of an RF signal and allowing a signal to be input with a minimum loss is connected to an input side of the first-stage transistor 128. An inter-stage matching circuit 133 is provided between the first-stage transistor 128 and the second-stage transistor 127. An inter-stage matching circuit 134 is provided between the second-stage transistor 127 and the third-stage transistor 126. A bias circuit 129 necessary for supplying DC power and an output matching circuit 135 necessary for sufficiently exploiting performance of the transistor 126 are connected to a collector side of the third-stage transistor 126. A base bias circuit 136 for supplying a base bias is connected to base sides of the transistors 126, 127 and 128.

FIG. 10 is a view schematically illustrating an example of a circuit arrangement of RF power amplifiers having the circuit configuration shown in FIG. 9. As illustrated in FIG. 10, to satisfy requirements of size reduction and low power consumption for RF power amplifiers, a hybrid integrated circuit in which a microwave integrated circuit advantageous to size reduction and a low-loss passive element advantageous to operation with low power consumption are incorporated is adopted. Specifically, as illustrated in FIG. 10, a monolithic microwave integrated circuit 141 incorporating circuit elements such as a transistor 138, metal-insulator-metal (MIM) capacitors 139 and spiral inductors 140 which are components of matching circuits is mounted on a dielectric substrate 137 constituting a hybrid integrated circuit. An output terminal of the transistor 138 is connected to a metal interconnection 181 on the dielectric substrate 137 through a wire 182. The metal interconnection 181 forms a microstrip transmission line 142 using, as a ground layer, a metal interconnect layer provided in a dielectric of the dielectric substrate 137. In addition to the monolithic microwave integrated circuit 141, chip capacitors 143, 144 and 145 and a chip inductor 146 are mounted on the dielectric substrate 137. The chip capacitors 143, 144 and 145 and the chip inductor 146 constitute the bias circuit 129 and the output matching circuit 135 shown in FIG. 9. Terminals 183 for external connection are provided on the rim of the dielectric substrate 137.

FIG. 11 illustrates an example of a circuit configuration of RF power amplifiers for a conventional multiband system on which two different communication systems, i.e., a global system for mobile communications (GSM) and a universal mobile telecommunications system (UMTS) are mounted. In the multiband system illustrated in FIG. 11, GSM-850 (a 850 MHz band) and GSM-900 (a 900 MHz band) need an RF power amplifier 147 for one system, a digital communication system (DCS) (a 1800 MHz band) and personal communication services (PCS) (1900 MHz) need an RF power amplifier 148 for one system, an UMTS band I (1920 to 1980 MHz) and an UMTS band II (1850 to 1910 MHz) need an RF power amplifier 149 for one system, an UMTS band III (1710 to 1785 MHz) and an UMTS band IV (1710 to 1755 MHz) need an RF power amplifier 150 for one system, and an UMTS band V (824 to 849 MHz) and an UMTS band VI (830 to 840 HMz) need an RF power amplifier 151 for one system. That is, it is necessary to provide the RF power amplifiers 147 through 151 for five systems in total. The circuit configuration of each of the RF power amplifiers 147 through 151 is the same as that shown in FIG. 9.
Patent Literature 1:

Japanese Unexamined Patent Publication No. 2005-277728
Patent Literature 2:

Japanese Unexamined Patent Publication No. 2005-244336 (particularly FIG. 2)

### SUMMARY OF THE INVENTION

In the conventional technique, RF power amplifiers having a circuit arrangement as illustrated in FIG. 10 are applied as a technique for configuring RF power amplifiers for five systems illustrated in FIG. 11. That is, five RF power amplifiers are mounted at the maximum on one mobile device. This not only greatly restricts size reduction of the mobile device but also requires cost corresponding to five systems, which was one system before the shift to multiband communication. Accordingly, the cost of a mobile device greatly increases.

FIG. 12 is a view illustrating a hybrid integrated circuit including RF power amplifiers for five systems configured using the circuit arrangement shown in FIG. 10. As illustrated in FIG. 12, monolithic microwave integrated circuits 153 and 154 in which RF power amplifiers for five systems are integrated are mounted on a dielectric substrate 152. Output terminals (for five systems) of transistors of the RF power amplifiers are connected to metal interconnection 191 formed on the dielectric substrate 152 through wires 192. Passive elements such as microwave transmission lines 193, chip capacitors 194, 195 and 196 and chip inductors 197 are mounted on the dielectric substrate 152. These passive elements constitute matching circuits for the transistors. The matching circuits provided for the RF power amplifiers serve as impedance converting circuits for converting an input impedance reduced to 1 to 30Ω so as to obtain a large current amplitude into a characteristic impedance of about 50Ω with a minimum loss. The monolithic microwave integrated circuits 153 and 154 and the dielectric substrate 152 on which the impedance converting circuits are placed are mounted on a mother board 201. Lines 202 provided on the surface of the mother board 201 are electrically connected to terminals 198 provided on the rim of the dielectric substrate 152.

As illustrated in FIG. 12, impedance converting circuits for five systems are needed for RF power amplifiers associated with five systems. RF signals input to these impedance converting circuits for the five systems have different frequencies, so that the impedance and the electrical length of a microwave transmission line as a component and the device constants of the passive elements such as chip capacitors and chip inductors as components differ among the impedance converting circuits. That is, since the impedance converting circuits differ from one another, the cost increases.

FIG. 13 is a cross-sectional view taken along the line B-B′ of FIG. 12. As illustrated in FIG. 13, metal interconnections 191A (an uppermost interconnection), 191B (a third-layer interconnection), 191C (a second-layer interconnection) and 191D (a first-layer interconnection) are formed in the dielectric substrate 152. Among the interconnections, the metal interconnections 191A and 191C are used as signal interconnect layers. The metal interconnections 191A and 191C face the respective metal interconnections 191B and 191D used as ground layers with a dielectric interposed therebetween, thereby forming microwave transmission lines. A plurality of through vias 161 reaching the bottom of the substrate through the surface thereof are provided in the dielectric substrate 152 on which the monolithic microwave integrated circuit 153 and other circuits are mounted. Heat generated in, for example, the monolithic microwave integrated circuit 153 is allowed to escape to the substrate bottom through the through vias 161 and released to the mother board 201. The through vias 161 not only serve as heat dissipation paths but also allow the monolithic microwave integrated circuit 153 and other circuits to be well grounded. If the number of through vias 161 is small, the transistors provided in, for example, the monolithic microwave integrated circuit 153 are insufficiently grounded. This not only causes characteristic degradation such as a decrease of a gain but also hinders stable operation to cause abnormal oscillation. Accordingly, a sufficient number of through vias 161 need to be provided. However, if the number of through vias 161 is too large, interconnections inside the dielectric substrate 152 cannot be used for purposes other than the ground interconnections in portions where the monolithic microwave integrated circuit 153, for example, is mounted. In this case, in the hybrid integrated circuit illustrated in FIG. 12, the dielectric substrate 152 with a multilayer structure cannot be effectively used for the area where the monolithic microwave integrated circuits 153 and 154 are mounted. As a result, redundant substrate costs are needed.

The dielectric substrate 152 protects a large number of various incorporated parts, so that the thickness of the dielectric substrate 152 needs to be set so as to secure not only electrical characteristics but also sufficient strength. In addition, to prevent degradation of RF performance of the hybrid integrated circuit, the thickness of a dielectric portion sandwiched between the metal interconnections 191B and 191D used as ground layers and the metal interconnections 191A and 191C used as signal interconnect layers needs to be sufficiently large. That is, to secure the strength and RF performance, a certain thickness or more of the dielectric substrate 152 needs to be set. Furthermore, to protect the surface of, for example, the monolithic microwave integrated circuit 153 mounted on the dielectric substrate 152 and the wires 192, the entire upper surface of the dielectric substrate 152 needs to be covered with a resin 163 having a sufficient thickness, as illustrated in FIG. 13. As a result, the hybrid integrated circuit including RF power amplifiers configured by the conventional technique becomes very thick and has a structure not suitable for mounting on thin mobile equipment such as a card-type electronic device.

It is therefore an object of the present invention to provide thin RF power amplifiers having excellent RF characteristics at low cost even in a case where RF power amplifiers for two or more systems need to be mounted to catch up with a shift to multiband communication of mobile equipment.

To achieve the object, an electronic device according to the present invention includes: a plurality of RF power amplifiers for amplifying RF signals having different frequencies; and an impedance converting circuit for receiving RF signals output from respective output terminals of the RF power amplifiers at a plurality of input terminals disposed to face the respective output terminals, and for performing impedance conversion. Specifically, in the electronic device of the present invention, a monolithic microwave integrated circuit serving as RF power amplifiers for a plurality of systems, for example, is mounted on a lead frame and sealed in, for example, a plastic package dedicated to a semiconductor integrated circuit using a resin mold, and an impedance converting circuit is provided on a dielectric substrate different from the monolithic microwave integrated circuit. The monolithic microwave integrated circuit sealed in the package and the dielectric substrate on which the impedance converting circuit is integrated are mounted on a mother board for the electronic device such as mobile equipment such that one side of the monolithic microwave integrated circuit closely faces one side of the impedance converting circuit. Input terminals of the impedance converting circuit are arranged to face the respective output terminals of transistors of the RF power amplifiers for two or more systems. In addition, a plurality of pairs each formed by one of the output terminals of the RF power amplifiers and associated one of the input terminals of the impedance converting circuit are regularly arranged in parallel.

In the electronic device of the present invention, the monolithic microwave integrated circuit, for example, forming the RF power amplifiers are not mounted on, for example, a dielectric substrate on which the impedance converting circuit is integrated, so that the thickness of the monolithic microwave integrated circuit is reduced. In addition, heat is dissipated from the back surface of the monolithic microwave integrated circuit to the mother board through a thin lead frame without passing through the dielectric substrate, thus implementing highly-reliable RF power amplifiers exhibiting excellent heat dissipation. Moreover, since the monolithic microwave integrated circuit is not mounted on a dielectric substrate, the distance to a ground layer for grounding the circuit is reduced, thus implementing RF power amplifier having excellent RF characteristics while suppressing gain degradation.

In the electronic device of the present invention, a real part of an input impedance of each of the RF signals input to the input terminals of the impedance converting circuit from the output terminals of the RF power amplifiers may be 1Ω or more and less then 30Ω, and the impedance converting circuit may convert the input impedance into an impedance having a real part of 30Ω or more.

In the electronic device of the present invention, means for changing at least one of an electrical length and an input impedance is preferably connected to at least one of the input terminals of the impedance converting circuit. Specifically, in actually incorporating RF power amplifiers for a plurality of systems and an impedance converting circuit provided in association with the RF power amplifiers into an electronic device such as mobile equipment, if means for previously correcting a deviation of an electrical length or an impedance for at least one system is provided, the positions of the monolithic microwave integrated circuit forming the RF power amplifiers and the impedance converting circuit are easily adjusted. In particular, in a case where lines for as many as five systems are needed, the foregoing configuration enables easy implementation of the impedance converting circuit in which electrical lengths or impedances for all the systems precisely match the optimum values.

In the electronic device of the present invention, it is preferable that at least two of lines connecting the input terminals of the impedance converting circuit and a plurality of output terminals of the impedance converting circuit associated with the respective input terminals intersect with each other, thereby making the order of arrangement of the input terminals and the order of arrangement of the output terminals differ from each other. Then, even in a case where the output terminals of the impedance converting circuit need to be arranged in different order from that of arrangement of RF power amplifiers for two or more systems because of, for example, connection position of an antenna or other parts mounted on the electronic device such as mobile equipment, only the order of arrangement of the output terminals of the impedance converting circuit is allowed to be flexibly changed without a change of any of the order of arrangement of output terminals of the monolithic microwave integrated circuit forming the RF power amplifiers and the order of arrangement of components (except for lines) in the impedance converting circuit.

In the electronic device of the present invention, the impedance converting circuit may include a bias supplying circuit for supplying a DC power supply voltage necessary for operating a transistor used in at least one of the RF power amplifiers through an associated one of the output terminals of the RF power amplifiers. In this case, terminals for supplying bias to bias supplying circuits for two or more systems in the impedance converting circuit are united into one terminal, so that the need for providing a plurality of complicated lines on the mother board of the electronic device such as mobile equipment is eliminated.

In the electronic device of the present invention, the impedance converting circuit preferably includes one of a coupler for detecting an RF signal passing through at least one of the output terminals for outputting. RF signals subjected to impedance conversion and an additional terminal for outputting the detected signal. Then, it is possible to appropriately control signals output from an electronic device such as mobile equipment.

In the electronic device of the present invention, if the impedance converting circuit includes a bias supplying circuit for supplying a DC power supply voltage necessary for operating a transistor used in at least one of the RF power amplifiers through the output terminal of the RF power amplifier, the impedance converting circuit preferably includes, between a DC-power-supply-voltage supplying terminal of the bias supplying circuit and a ground, a protection circuit for bypassing a surge component so as to protect a transistor used in one of the RF power amplifiers. Then, a surge component having a relatively low frequency is bypassed from the bias supplying circuit designed to prevent leakage of an amplified RF signal, thus ensuring protection of transistors used in the RF power amplifiers (i.e., the monolithic microwave integrated circuit).

In the electronic device of the present invention, it is preferable that at least one of the output terminals of the RF power amplifiers is output terminals of a balanced circuit, the output terminals are composed of a pair of terminals, the impedance converting circuit includes input terminals of another balanced circuit, and the input terminals are composed of a pair of terminals disposed to face the output terminals of the balanced circuit. Then, even in a case where transistors of, for example, the monolithic microwave integrated circuit serving as RF power amplifiers produce balanced output of RF signals, since the monolithic microwave integrated circuit and the impedance converting circuit are disposed to closely face each other, only setting the input side of the impedance converting circuit to enable balanced inputs allows easy connection between the monolithic microwave integrated circuit and the impedance converting circuit.

In the electronic device of the present invention, the impedance converting circuit preferably includes a microwave transmission line in which a signal line and a ground line are placed in a dielectric substrate, as means for converting an impedance. Then, it is possible to minimize leakage and a loss of RF signals, so that efficiency in converting RF signals is enhanced.

In the electronic device of the present invention, if the impedance converting circuit includes a bias supplying circuit for supplying a DC power supply voltage necessary for operating a transistor used in at least one of the RF power amplifiers through the output terminal of the RF power amplifier, the impedance converting circuit preferably includes a microwave transmission line in which a signal line and a ground line are placed in a dielectric substrate, as means for forming the bias supplying circuit. This enables a DC power supply voltage to be supplied with a minimum loss of an RF signal, so that power consumption of the electronic device such as mobile equipment is reduced.

In the electronic device of the present invention, if the impedance converting circuit includes the microwave transmission line, the ground line forming the microwave transmission line is preferably divided into portions associated with the respective RF power amplifiers. Specifically, the signal line of the impedance converting circuit associated with RF power amplifiers for two or more systems is divided into portions associated with the respective RF power amplifiers as well as the ground layer provided in the dielectric substrate to form the microwave transmission line in the impedance converting circuit is divided into portions associated with the respective RF power amplifiers. Accordingly, even in a case where microwave transmission lines for respective systems are closely located in the impedance converting circuit, interference among the microwave transmission lines for the systems, i.e., leakage of a signal from one microwave transmission lines to another is suppressed.

As described above, according to the present invention, even when a shit to multiband of mobile equipment causes the need for incorporating RF power amplifiers for two or more systems, it is possible to provide thin RF power amplifiers having excellent RF characteristics at low cost. Specifically, a monolithic microwave integrated circuit forming RF power amplifiers, for example, is mounted on a lead frame and sealed in, for example, a plastic package dedicated for a semiconductor integrated circuit using a resin mold, so that the monolithic microwave integrated circuit does not need to be mounted on a substrate on which an impedance converting circuit is integrated. Accordingly, the electronic device of the present invention is advantageous to thickness reduction. In addition, heat is directly dissipated from the back surface of the monolithic microwave integrated circuit to a mother board through the lead frame, so that heat dissipation is better than the case of mounting the monolithic microwave integrated circuit on a dielectric substrate. Moreover, since the monolithic microwave integrated circuit is not mounted on a dielectric substrate, the distance to a ground layer for grounding the circuit is reduced, thus implementing RF power amplifiers having excellent RF characteristics.

Accordingly, the present invention is useful for, for example, RF power amplifiers in mobile equipment suitable to functional enhancement and high-value-added service of mobile communication systems such as a cellular phone network.

### BRIEF DESCRIPTION OF THE DRAWINGS

FIG. 1 is an equivalent circuit diagram illustrating an example of a configuration of an electronic device according to a first embodiment of the present invention.

FIG. 2 is a view schematically illustrating an example of a circuit arrangement according to the first embodiment.

FIG. 3 is a cross-sectional view taken along the line A-A′ in FIG. 2.

FIG. 4 is an equivalent circuit diagram illustrating an example of a configuration of an electronic device according to a second embodiment of the present invention.

FIG. 5 is an equivalent circuit diagram illustrating an example of a configuration of an electronic device according to a third embodiment of the present invention.

FIG. 6 is an equivalent circuit diagram illustrating an example of a configuration of an electronic device according to a fourth embodiment of the present invention.

FIG. 7 is an equivalent circuit diagram illustrating an example of a configuration of an electronic device according to a fifth embodiment of the present invention.

FIG. 8 is a cross-sectional view illustrating an example of a configuration of an electronic device according to an eighth embodiment of the present invention and corresponds to a cross-sectional view taken along the line C-C′ in FIG. 2.

FIG. 9 is an equivalent circuit diagram illustrating an example of a configuration of a conventional RF power amplifier.

FIG. 10 is a view schematically illustrating an example of a circuit configuration of conventional RF power amplifiers.

FIG. 11 is an equivalent circuit diagram illustrating an example of a configuration of RF power amplifiers for a conventional multiband system.

FIG. 12 is a view illustrating an example of a configuration of a conventional hybrid integrated circuit including RF power amplifiers for five systems.

FIG. 13 is a cross-sectional view taken along the line B-B′ in FIG. 12.

### DETAILED DESCRIPTION OF THE INVENTION

### Embodiment 1

Hereinafter, an electronic device according to a first embodiment of the present invention will be described with reference to the drawings.

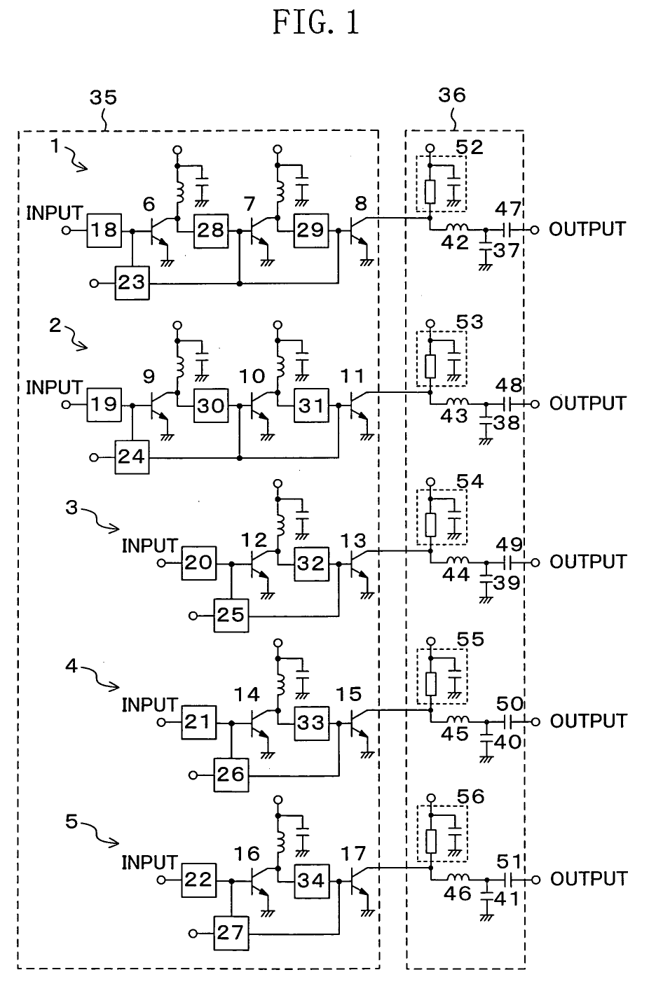

FIG. 1 is an equivalent circuit diagram showing an example of a configuration of the electronic device of this embodiment. As shown in FIG. 1, the electronic device of this embodiment includes RF power amplifiers 1, 2, 3, 4 and 5 for five systems. Each of the RF power amplifiers 1 and 2 for two systems has a three-stage amplifying configuration. Specifically, the RF power amplifier 1 includes transistors 6, 7 and 8, which are three bipolar transistors connected in series, and the RF power amplifier 2 includes transistors 9, 10 and 11, which are three bipolar transistors connected in series. Each of the RF power amplifiers 3, 4 and 5 for three systems has a two-stage amplifying configuration. Specifically, the RF power amplifier 3 includes transistors 12 and 13, which are two bipolar transistors connected in series, the RF power amplifier 4 includes transistors 14 and 15, which are two bipolar transistors connected in series, and the RF power amplifier 5 includes transistors 16 and 17, which are two bipolar transistors connected in series. In the RF power amplifiers 1 through 5, input matching circuits 18, 19, 20, 21 and 22 are connected to the respective input sides of the first-stage transistors and base bias circuits 23, 24, 25, 26 and 27 are connected to the respective base sides of the respective transistors. In addition, inter-stage matching circuits 28, 29, 30, 31, 32, 33 and 34 each for establishing matching between transistors at cascadable stages and bias circuits for supplying base current so as to obtain desired collector current from the respective transistors are provided. In this embodiment, the RF power amplifiers 1 through 5 for the five systems described above are integrated in a monolithic microwave integrated circuit and the integrated circuit is sealed in one package 35.

The electronic device of this embodiment is characterized by including an impedance converting circuit 36 having five input terminals disposed to face the output terminals of the respective RF power amplifiers 1 through 5 for the five systems. The impedance converting circuit 36 serves as an output matching circuit for the transistors 8, 11, 13, 15 and 17 at the last stages in the respective RF power amplifiers 1 through 5 for five systems and coverts input impedance of a low impedance (e.g., 1 through 30Ω) in order to secure maximum power amplification into a higher impedance of, for example, about 50Ω. In the impedance converting circuit 36, shunt capacitors 37, 38, 39, 40 and 41 for reducing the real part of impedance and serial inductors 42, 43, 44, 45 and 46 for adjusting the imaginary part of impedance according to the frequency band to be used are provided for the respective transistors 8, 11, 13, 15 and 17 at the last stages of the RF power amplifiers 1 through 5 for five systems. The impedance converting circuit 36 also includes: bias supplying circuits 52, 53, 54, 55 and 56 for supplying DC power supply voltages to the respective transistors 8, 11, 13, 15 and 17 at the last stages through the output terminals of the RF power amplifiers 1 through 5 for five systems and; series capacitors 47, 48, 49, 50 and 51 for preventing direct current supplied from the bias supplying circuits 52, 53, 54, 55 and 56 from flowing into the output side of the impedance converting circuit 36.

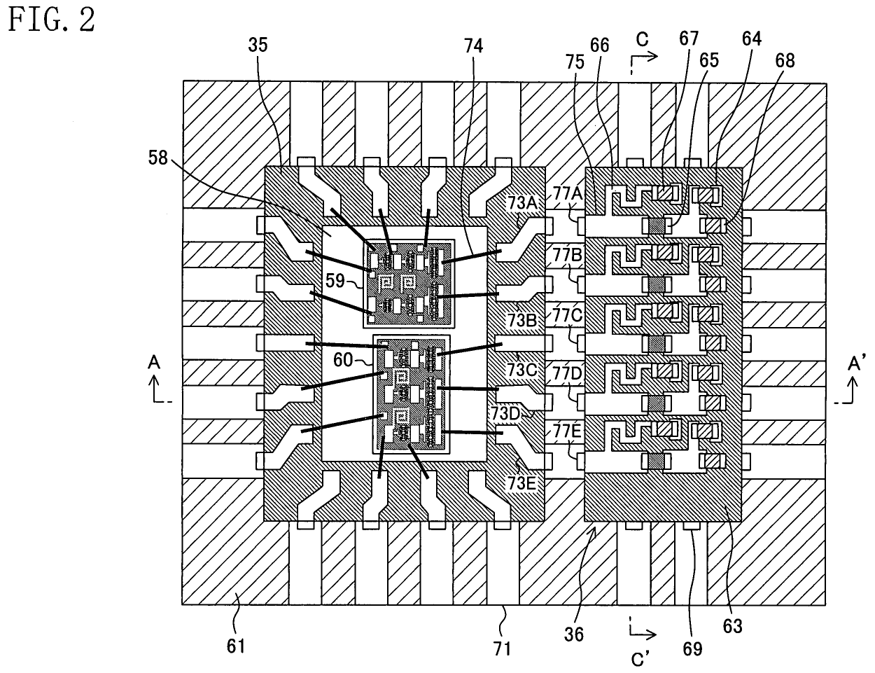

FIG. 2 is a view schematically illustrating an example of a circuit arrangement of the electronic device with the circuit configuration shown in FIG. 1. As illustrated in FIG. 2, monolithic microwave integrated circuits 59 and 60 in which RF power amplifiers for five systems are integrated are mounted on a die bonding pad 58 and are sealed in the plastic package 35. The plastic package 35 is mounted on a mother board 61 for the electronic device such as mobile equipment, together with a dielectric substrate 63 on which the impedance converting circuit 36 is integrated.

The plastic package 35 is provided with a plurality of lead terminals 73. The lead terminals 73 are electrically connected to the monolithic microwave integrated circuits 59 and 60 through a plurality of wires 74. The outputs of the transistors at the last stages of the RF power amplifiers for five systems are connected to input terminals 77A, 77B, 77C, 77D and 77E of the impedance converting circuit 36 through the wires 74 and the lead terminals (output terminals) 73A, 73B, 73C, 73D and 73E. The output terminals 73A through 73E of the RF power amplifiers for five systems and the input terminals 77A through 77E of the impedance converting circuit 36 are electrically connected to each other through lines 71 provided on the surface of the mother board 61. A pair of the output terminal 73A and the input terminal 77A, a pair of the output terminal 73B and the input terminal 77B, a pair of the output terminal 73C and the input terminal 77C, a pair of the output terminal 73D and the input terminal 77D and a pair of the output terminal 73E and the input terminal 77E are regularly arranged in parallel.

Chip capacitors 64 used as shunt capacitors and chip inductors 65 used as serial inductors are provided as components of the impedance converting circuit 36 on the dielectric substrate 63 on which the impedance converting circuit 36 is integrated. Electrical connection among the input terminals 77, the chip capacitors 64 and the chip inductors 65 is established by a metal interconnect layer 75. The impedance converting circuit 36 includes bias supplying circuits for supplying DC power supply voltages to the respective transistors at the last stages of the RF power amplifiers for five systems. Each of the bias supplying circuits includes a microwave transmission line 66 and an RF bypass capacitor 67 formed on the dielectric substrate 63. Alternating current is short-circuited at the terminal to which the RF bypass capacitor 67 is connected. The line length of the microwave transmission line 66 is determined in consideration of an electrical length at the frequency to be used so that the connection point between the microwave transmission line 66 and the impedance converting circuit 36 is sufficiently open. Series capacitors 68 are also connected to the impedance converting circuit 36 to prevent direct current supplied from the bias supplying circuits from flowing to the output side of the impedance converting circuit 36. The series capacitors 68 for five systems are arranged in parallel, the chip capacitors 64 used as shunt capacitors for five systems are arranged in parallel, the chip inductors 65 used as serial inductors for five systems are arranged in parallel, the microwave transmission lines 66 for five systems are arranged in parallel, and the RF bypass capacitors 67 for five systems are arranged in parallel. The microwave transmission lines 66 and the RF bypass capacitors 67 constitute the bias supplying circuits. Lines used for supplying DC power supply voltages to the bias supplying circuits for five systems are shared when necessary. The DC power supply voltages are supplied to the respective bias supplying circuits from outside the device by way of one terminal 69 provided on the impedance converting circuit 36 (i.e., the dielectric substrate 63).

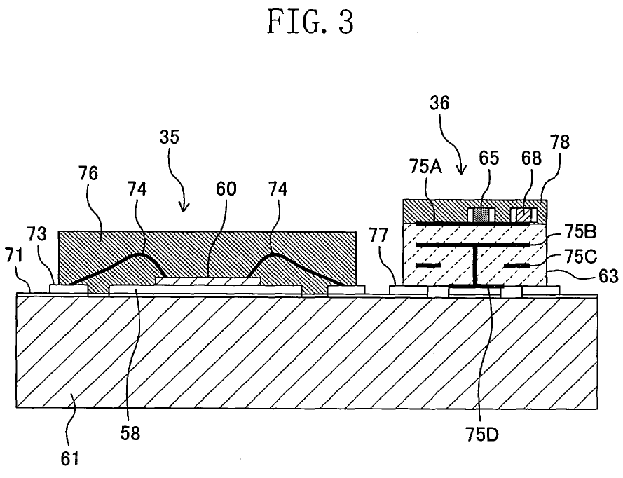

FIG. 3 is a cross-sectional view taken along the line A-A′ in FIG. 2. As illustrated in FIG. 3, the monolithic microwave integrated circuit 60 and other components are mounted on the die bonding pad 58 in the plastic package 35. The plurality of lead terminals 73 are provided at the rim of the plastic package 35. The upper portion of, for example, the monolithic microwave integrated circuit 60 and the wires 74 for connection are protected by a sealing resin 76 for surface protection. The plastic package 35 is mounted on the mother board 61. The impedance converting circuit 36 is configured on the dielectric substrate 63. The dielectric substrate 63 has a multilayer interconnect structure in which metal interconnect layers 75A (an uppermost interconnection), 75B (a third-layer interconnection), 75C (a second-layer interconnection) and 75D (a first-layer interconnection) are placed in its dielectric. The chip capacitors 64 and the chip inductors 65, for example, are mounted on the surface of the dielectric substrate 63. The chip capacitors 64, for example, are protected on the dielectric substrate 63 by a sealing resin 78 for surface protection. Instead of the sealing resin 78, a metal case may be used.

In this embodiment, the metal interconnect layer 75A is used as a signal line and the metal interconnect layer 75B is used as a ground layer, thereby forming microstrip lines, which are an example of microwave transmission lines. The microstrip lines are used as the microwave transmission lines 66 for the bias supplying circuits. This allows DC power supply voltages to be supplied with a minimum loss of RF signals, so that power consumption of the electronic device such as mobile equipment is reduced.

In this embodiment, a dielectric is sandwiched between the metal interconnect layer 75C and each of the metal interconnect layers 75B and 75D, using the metal interconnect layer 75C as a signal line and the metal interconnect layers 75B and 75D as ground layers, thereby forming strip lines, which are an example of microwave transmission lines. The strip lines are used as means for converting impedance. This minimizes leakage and a loss of an RF signal so that the efficiency in converting an RF signal is enhanced. In addition, the strip lines may be used as microwave transmission lines for the bias supplying circuits, in the same manner as the microstrip lines.

In this embodiment, the metal interconnect layer 75C is used to unite terminals for supplying DC power supply voltages to a plurality of bias supplying circuits associated with a plurality of RF power amplifiers into one terminal. This eliminates the need for providing a plurality of complicated lines on the mother board 61 of the electronic device such as mobile equipment. However, as described above, the metal interconnect layer 75C also serves as microwave transmission lines and may be used as a part of the bias supplying circuits.

As described above, in the first embodiment, the monolithic microwave integrated circuits 59 and 60 forming RF power amplifiers for a plurality of systems are not mounted on the dielectric substrate 63 on which the impedance converting circuit 36 is integrated, so that the thickness of the monolithic microwave integrated circuits 59 and 60 is reduced. In addition, heat is dissipated from the back surfaces of the monolithic microwave integrated circuits 59 and 60 to the mother board 61 through a thin lead frame (i.e., the die bonding pad 58) without passing through the dielectric substrate 63, thus implementing highly-reliable RF power amplifiers exhibiting excellent heat dissipation. Furthermore, since the monolithic microwave integrated circuits 59 and 60 are not mounted on the dielectric substrate 63, the distance to the ground layer for grounding the circuits is reduced, so that RF power amplifiers having excellent RF characteristics are implemented with gain degradation suppressed.

### Embodiment 2

Hereinafter, an electronic device according to a second embodiment of the present invention will be described with reference to the drawings.

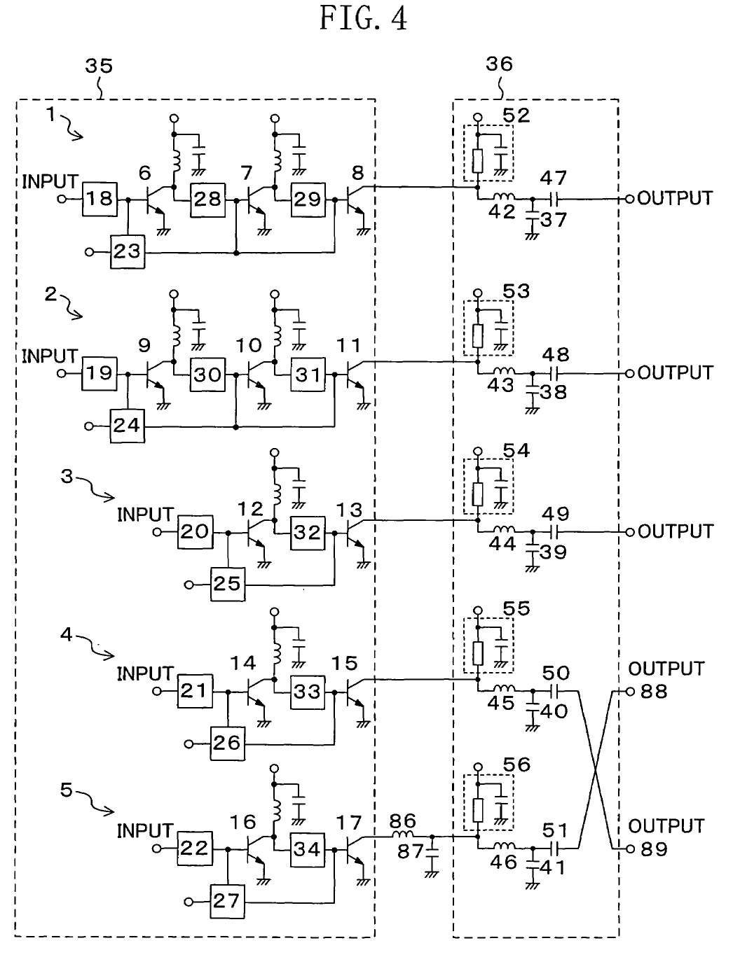

FIG. 4 is an equivalent circuit diagram illustrating an example of a configuration of the electronic device of this embodiment. In FIG. 4, components also shown in FIG. 1 for the first embodiment are denoted by the same reference numerals, and thus description thereof will be omitted. As illustrated in FIG. 4, in the electronic device of this embodiment, as in the electronic device of the first embodiment including the RF power amplifiers for five systems shown in FIG. 1, a package 35 incorporating RF power amplifiers 1 through 5 (formed as a monolithic microwave integrated circuit) and an impedance converting circuit 36 are disposed to face each other.

The second embodiment is different from the first embodiment in that a serial inductor 86 for increasing an electrical length and a shunt capacitor 87 for reducing an electrical length are provided between an output terminal of the RF power amplifier 5 for one system out of the RF power amplifiers 1 through 5 for five systems and an input terminal of the impedance converting circuit 36 electrically connected to this output terminal.

With the foregoing characteristic, in actually mounting the package 35 incorporating a monolithic microwave integrated circuit and the impedance converting circuit 36 on a mother board of the electronic device such as mobile equipment, even if it is difficult to precisely adjust the electrical lengths necessary for connection of the respective five systems to optimum values by adjusting the positions of the package 35 and the impedance converting circuit 36, the electrical length changing means 86 and 87 shown in FIG. 4 enables the adjustment so that performances of the RF power amplifiers 1 through 5 for five systems are exhibited with stability.

Other aspects in which the second embodiment is different from the first embodiment are that a line connecting an input terminal of the impedance converting circuit 36 associated with the RF power amplifier 4 and an output terminal 89 of the impedance converting circuit 36 associated with the input terminal and a line connecting an input terminal of the impedance converting circuit 36 associated with the RF power amplifier 5 and an output terminal 88 of the impedance converting circuit 36 associated with the input terminal intersect with each other, and that the order of arrangement of input terminals of the impedance converting circuit 36 differs from the order of arrangement of corresponding output terminals of the impedance converting circuit 36.

With the foregoing characteristics, even when the output terminals of the impedance converting circuit 36 need to be arranged in different order from the arrangement of the RF power amplifiers 1 through 5 for five systems because of the connection position of, for example, antennas of the electronic device such as mobile equipment, the lines for the systems intersect with each other immediately before the output terminals of the impedance converting circuit 36 (after components substantially constituting the impedance converting circuit) so that only the order of arrangement of the output terminals of the impedance converting circuit 36 is allowed to be flexibly changed without a change of the order of arrangement of the output terminals of the package 35 and a change of the order of arrangement of components (except for lines) of the impedance converting circuit 36.

In the second embodiment, means for changing an electrical length is provided for an input terminal of the impedance converting circuit 36 associated with one system. Alternatively, means for changing electrical lengths may be provided for input terminals associated with two or more systems. Instead of, or in addition to, the means for changing an electrical length, means for changing input impedance may be provided. Specifically, if a capacitor is connected in parallel with a connection line between an output terminal of an RF power amplifier and an input terminal of the impedance converting circuit, input impedance is reduced. If either an inductor and a capacitor or a microwave transmission line and a capacitor are connected to the connection line, the input impedance is increased or reduced.

In the second embodiment, lines associated with two systems intersect with each other in the impedance converting circuit 36. Alternatively, lines associated with three or more systems may intersect with each other.

### Embodiment 3

Hereinafter, an electronic device according to a third embodiment of the present invention will be described with reference to the drawings.

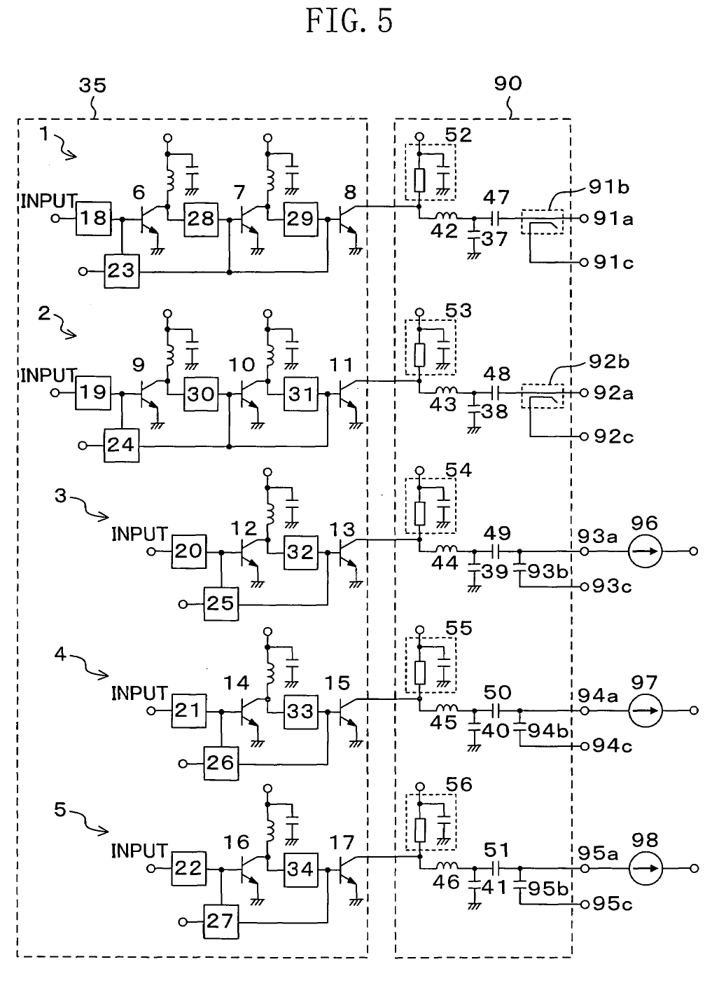

FIG. 5 is an equivalent circuit diagram illustrating an example of a configuration of the electronic device of this embodiment. In FIG. 5, components also shown in FIG. 1 for the first embodiment are denoted by the same reference numerals, and thus description thereof will be omitted.

As illustrated in FIG. 5, the third embodiment is different from the first embodiment in that the impedance converting circuit 36 of the first embodiment is replaced by an impedance converting circuit 90. As illustrated in FIG. 5, in the electronic device of this embodiment, output terminals of a package 35 incorporating RF power amplifiers 1 through 5 (configured as a monolithic microwave integrated circuit) and input terminals of the impedance converting circuit 90 are arranged to face each other, as in the connection relationship between the RF power amplifiers 1 through 5 and the impedance converting circuit 36 in the electronic device of the first embodiment illustrated in FIG. 1.

The internal configuration of the impedance converting circuit 90 of this embodiment is characterized in that directional couplers 91b and 92b are provided immediately before respective output terminals 91a and 92a (i.e., after components substantially constituting the impedance converting circuit) in order to detect a part of RF signals passing through the output terminals 91a and 92a out of a plurality of output terminals 91a, 92a, 93a, 94a and 95a for outputting RF signals subjected to impedance conversion, as shown in FIG. 5. The signals detected by the directional couplers 91b and 92b are output from the respective terminals 91c and 92c.

Another characteristic of this embodiment is that isolators 96, 97 and 98 for causing signals to pass only in one direction are connected to the respective output terminals 93a, 94a and 95a outside the impedance converting circuit 90. This eliminates the need for limiting the directivity of signals passing through the output terminals 93a, 94a and 95a. Accordingly, capacitors 93b, 94b and 95b provided immediately before the output terminals 93a, 94a and 95a (i.e., after components substantially constituting the impedance converting circuit) allow a part of signals passing through the output terminals 93a, 94a and 95a to be taken from terminals 93c, 94c and 95c.

In the third embodiment, it is possible to appropriately control signals output from the electronic device such as mobile equipment.

In the third embodiment, couplers for detecting RF signals or additional terminals for outputting the detected signals are provided for all the output terminals of the impedance converting circuit 90. However, the present invention is not limited to this, and it is sufficient to provide a coupler for detecting an RF signal or an additional terminal for outputting the detected signal for at least one output terminal at which signal detection is needed.

In this embodiment, based on the configuration of the first embodiment, couplers for detecting RF signals or additional terminals for outputting the detected signals are provided for the output terminals of the impedance converting circuit. Alternatively, based on the configuration of the second embodiment shown in FIG. 4, couplers for detecting RF signals or additional terminals for outputting the detected signals may be provided for output terminals of the impedance converting circuit.

### Embodiment 4

Hereinafter, an electronic device according to a fourth embodiment of the present invention will be described with reference to the drawings.

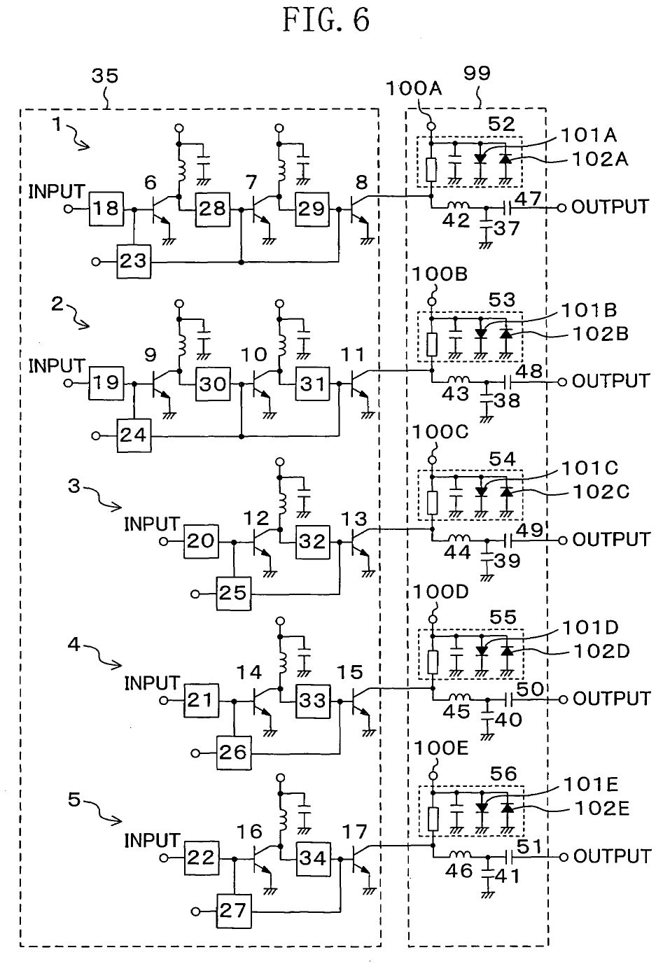

FIG. 6 is an equivalent circuit diagram illustrating an example of a configuration of the electronic device of this embodiment. In FIG. 6, components also shown in FIG. 1 for the first embodiment are denoted by the same reference numerals, and thus description thereof will be omitted.

The fourth embodiment is different from the first embodiment in that as illustrated in FIG. 6, the impedance converting circuit 36 of the first embodiment is replaced by an impedance converting circuit 99. As illustrated in FIG. 6, in the electronic device of this embodiment, output terminals of a package 35 incorporating RF power amplifiers 1 through 5 (configured as a monolithic microwave integrated circuit) and input terminals of the impedance converting circuit 99 are arranged to face each other, as in the connection relationship between the RF power amplifiers 1 through 5 and the impedance converting circuit 36 in the electronic device of the first embodiment illustrated in FIG. 1.

As illustrated in FIG. 6, the internal configuration of the impedance converting circuit 99 of this embodiment is characterized in that protection diodes 101A and 102A are connected in parallel between a DC-power-supply-voltage supplying terminal 100A of a bias supplying circuit 52 and the ground. In the same manner, protection diodes 101B and 102B are connected in parallel between a DC-power-supply-voltage supplying terminal 100B of a bias supplying circuit 53 and the ground, protection diodes 101C and 102C are connected in parallel between a DC-power-supply-voltage supplying terminal 100C of a bias supplying circuit 54 and the ground, protection diodes 101D and 102D are connected in parallel between a DC-power-supply-voltage supplying terminal 100D of a bias supplying circuit 55 and the ground, and protection diodes 101E and 102E are connected in parallel between a DC-power-supply-voltage supplying terminal 100E of a bias supplying circuit 56 and the ground. In this manner, a protection circuit capable of bypassing a surge component having a relatively low frequency is configured for each of the bias supplying circuits 52 through 56.

In the fourth embodiment, a surge component having a relatively low frequency is allowed to be bypassed from the bias supplying circuits 52 through 56 designed to prevent leakage of amplified RF signals, thus ensuring protection of transistors used in the RF power amplifiers 1 through 5.

In the fourth embodiment, the protection circuit is provided between the DC-power-supply-voltage supplying terminal of each of the bias supplying circuits 52 through 56 and the ground. However, the present invention is not limited to this, and the protection circuit may be provided between the DC-power-supply-voltage supplying terminal of at least one bias supplying circuit and the ground.

In the fourth embodiment, the diodes connected between the DC-power-supply-voltage supplying terminals of the respective bias supplying circuits 52 through 56 and the grounds so as to configure protection circuits may be serially connected in multiple stages, may be arranged in parallel in opposite directions or may be arranged in parallel in one direction, according to assumed values of applied voltages, polarities and current to be bypassed, for example. Instead of protection diodes in a small number of stages, a semiconductor ceramic such as a positive temperature coefficient (PTC) thermistor whose resistance decreases upon application of a high voltage may be used as a component of a protection circuit.

In the fourth embodiment, based on the configuration of the first embodiment, the protection circuit is provided between the DC-power-supply-voltage supplying terminal of each of the bias supplying circuits and the ground. Alternatively, based on the configuration of the second embodiment shown in FIG. 4, the configuration of the third embodiment shown in FIG. 5 or a combination of these configurations, a protection circuit may be provided between the DC-power-supply-voltage supplying terminal of each of the bias supplying circuits and the ground.

### Embodiment 5

Hereinafter, an electronic device according to a fifth embodiment of the present invention will be described with reference to the drawings.

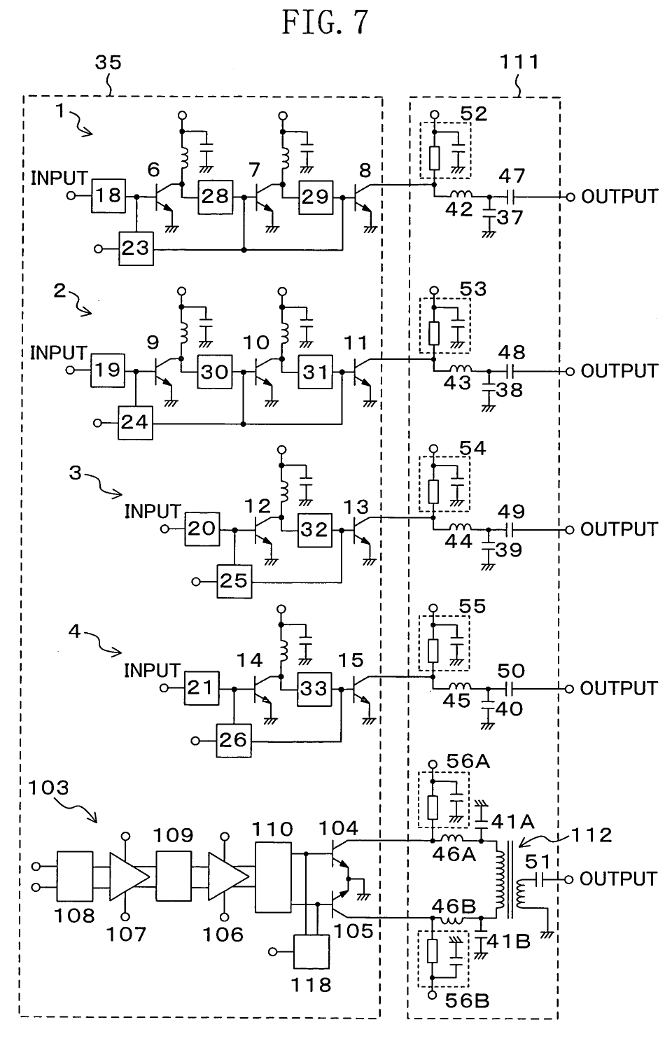

FIG. 7 is an equivalent circuit diagram illustrating an example of a configuration of the electronic device of this embodiment. In FIG. 7, components also shown in FIG. 1 for the first embodiment are denoted by the same reference numerals, and thus description thereof will be omitted.

A first aspect in which the fifth embodiment is different from the first embodiment is that as illustrated in FIG. 7, an RF power amplifier 5 out of RF power amplifiers 1 through 5 forming a monolithic microwave integrated circuit in a package 35 is replaced by an RF power amplifier 103 for one system formed by a balanced circuit. Specifically, the RF power amplifier 103 has a three-stage amplifying configuration including: a pair of transistors 104 and 105 at the last stage; a balanced amplifier 106 at the second stage; and a balanced amplifier 107 at the first stage. An input matching circuit 108 formed by a balanced circuit is provided at the input side of the balanced amplifier 107. An inter-stage matching circuit 109 is provided between the balanced amplifier 106 and the balanced amplifier 107. An inter-stage matching circuit 110 is provided between the balanced amplifier 106 and each of the transistors 104 and 105. A bias circuit is incorporated in each of the balanced amplifiers 106 and 107. A bias circuit 118 for supplying base current to the transistors 104 and 105 is connected to the input sides of the transistors 104 and 105.

A second aspect in which the fifth embodiment is different from the first embodiment is that as illustrated in FIG. 7, an impedance converting circuit 111 is provided instead of the impedance converting circuit 36 of the first embodiment. As shown in FIG. 7, in the electronic device of this embodiment, output terminals of a package 35 incorporating the RF power amplifiers 1 through 4 and 103 and input terminals of the impedance converting circuit 111 are arranged to face each other, as in the connection relationship between the RF power amplifiers 1 through 5 and the impedance converting circuit 36 in the electronic device of the first embodiment shown in FIG. 1. Outputs from the transistors 104 and 105 of the RF power amplifier 103 are balanced outputs, so that two lines extend as a pair from the output terminals (i.e., a pair of terminals) to corresponding input terminals (i.e., a pair of terminals) of the impedance converting circuit 111.

In the impedance converting circuit 111 of this embodiment, as shown in FIG. 7, shunt capacitors 41A and 41B for reducing the real part of impedance, serial inductors 46A and 46B for adjusting the imaginary part of impedance according to the frequency band to be used and bias supplying circuits 56A and 56B for supplying DC power supply voltages to the respective transistors 104 and 105 of the RF power amplifier 103 are provided for respective input terminals of the equivalent circuit associated with output terminals of the balanced circuit of the RF power amplifier 103. The impedance converting circuit 111 of this embodiment further includes a balun 112 for converting balanced lines on which the signals are transmitted into one signal line after impedance conversion on signals input from the input terminals of the balanced circuit. This eliminates the need for balanced lines after the output terminals of the impedance converting circuit 111, so that line design on the mother board is simplified. In the impedance converting circuit 111 of this embodiment, a series capacitor 51 is placed after the balun 112 in order to prevent direct current supplied from the bias supplying circuits 56A and 56B from flowing toward the output side of the impedance converting circuit 111.

In the fifth embodiment, even in a case where transistors of the RF power amplifier 103 in the monolithic microwave integrated circuit produce balanced outputs of RF signals, since the monolithic microwave integrated circuit and the impedance converting circuit 111 are closely disposed to face each other, only setting the input side of the impedance converting circuit 111 to enable balanced inputs allows easy connection between the monolithic microwave integrated circuit and the impedance converting circuit 111.

In the fifth embodiment, lines associated with one system in the impedance converting circuit 111 are balanced lines. Alternatively, lines associated with two or more systems may be balanced lines.

In the fifth embodiment, based on the configuration of the first embodiment, balanced lines are used. Alternatively, based on the configuration of the second embodiment shown in FIG. 4, the configuration of the third embodiment shown in FIG. 5, the configuration of the fourth embodiment shown in FIG. 6, or a combination of two or more of the configurations of the second through fourth embodiments, balanced lines may be used.

### Embodiment 6

Hereinafter, an electronic device according to a sixth embodiment of the present invention will be described with reference to the drawings.

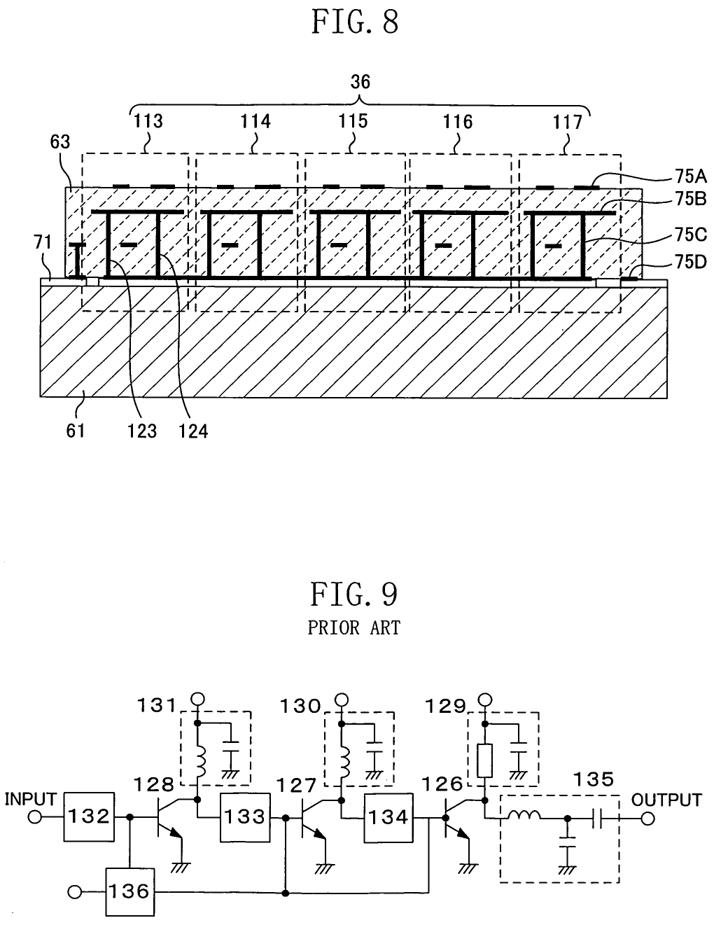

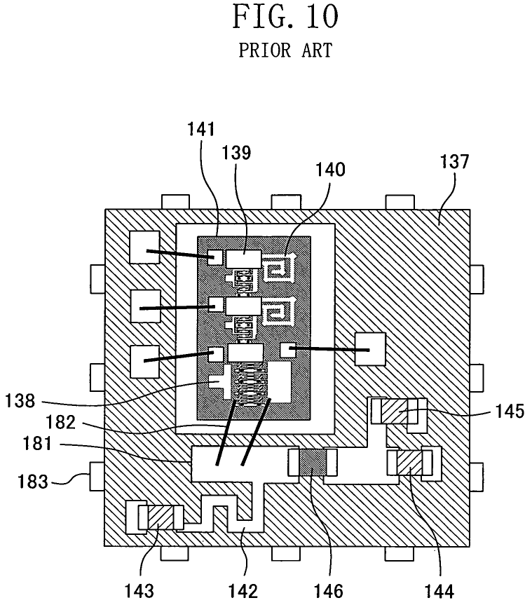

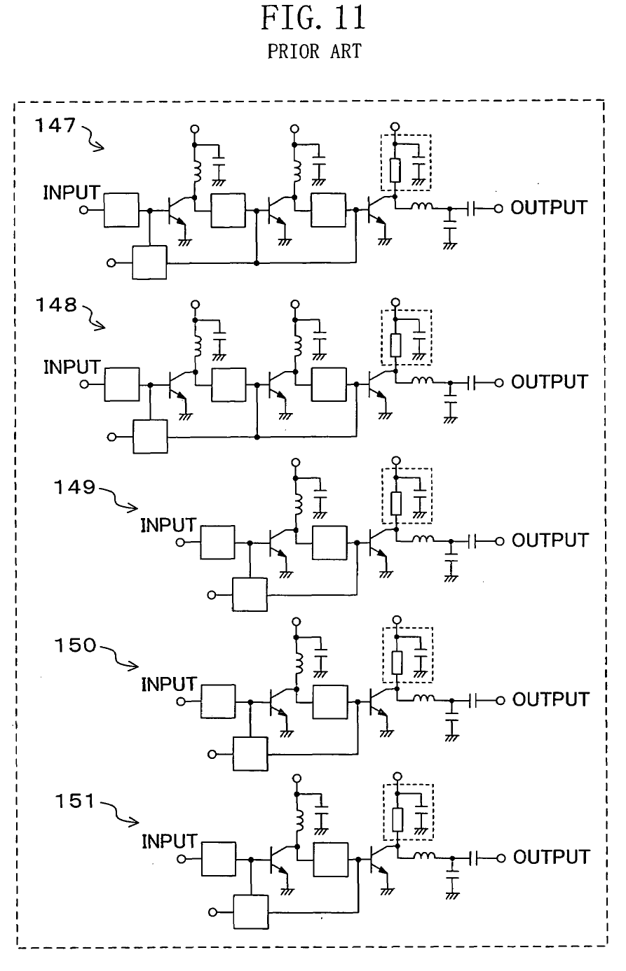

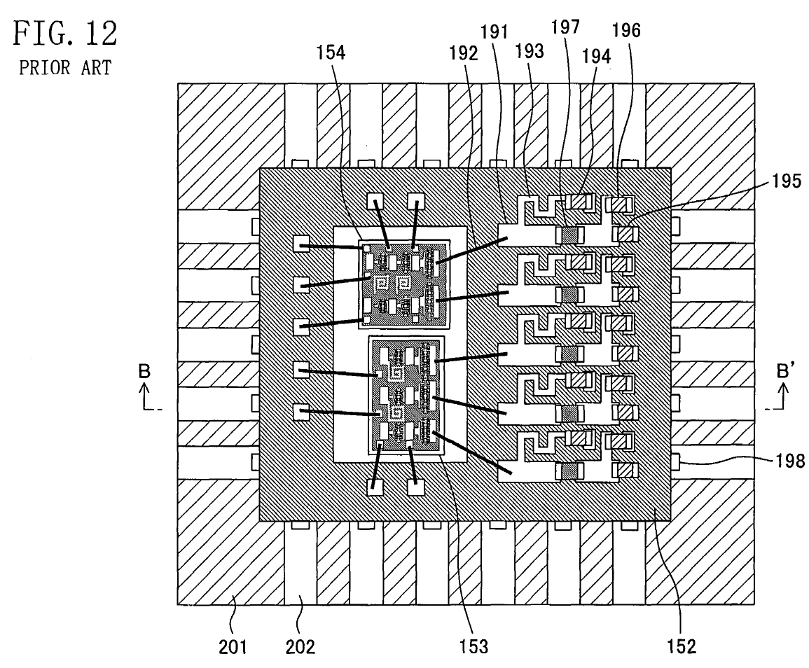

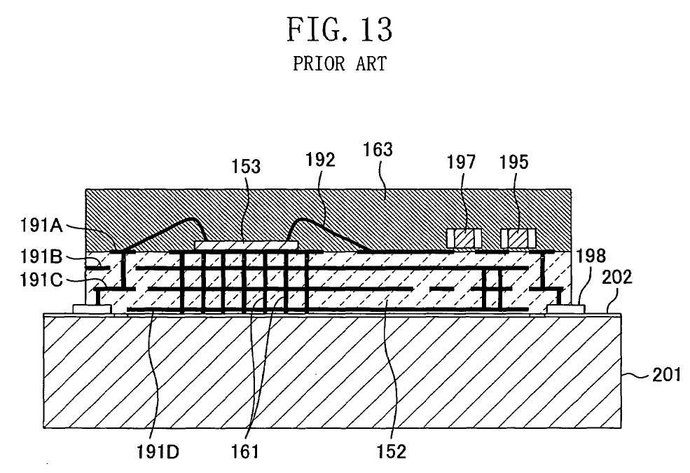

FIG. 8 is a cross-sectional view showing an example of a configuration of the electronic device of this embodiment and corresponds to a cross-sectional view taken along the line C-C′ in FIG. 2 showing the circuit arrangement of the first embodiment. As illustrated in FIG. 8, an impedance converting circuit 36 includes impedance converting circuits 113, 114, 115, 116 and 117 associated with RF power amplifiers for five systems. A dielectric substrate 63 on which the impedance converting circuit 36 is integrated has a multilayer interconnect structure in which metal interconnect layers 75A (an uppermost interconnection), 75B (a third-layer interconnection), 75C (a second-layer interconnection) and 75D (a first-layer interconnection) are placed in its dielectric. Chip capacitors and chip inductors, for example, which are components of the impedance converting circuit 36, are mounted on the metal interconnect layer 75A at the surface of the dielectric substrate 63. The metal interconnect layer 75A is used as a signal line and the metal interconnect layer 75B is used as a ground line, thereby forming microstrip lines, which are an example of microwave transmission lines. The metal interconnect layer 75A serving as signal lines is divided between each adjacent two of impedance converting circuits 113, 114, 115, 116 and 117. The metal interconnect layer 75B serving as a ground layer is connected to the metal interconnect layer 75D through vias 123 and 124. The metal interconnect layer 75D is connected to lines 71 provided on the surface of a mother board 61 of the electronic device such as mobile equipment.

This embodiment is characterized in that the metal interconnect layer 75B serving as a ground layer is divided between each adjacent two of the impedance converting circuits 113, 114, 115, 116 and 117. The portions of the metal interconnect layer 75B in the respective impedance converting circuits 113 through 117 are connected to the metal interconnect layer 75D through the vias 123 and 124.

In the sixth embodiment, even in a case where microwave transmission lines for respective systems are closely located in the impedance converting circuit 36, the characteristics described above suppress interference among the microwave transmission lines for the systems through the metal interconnect layer 75B which cannot form ideal ground, i.e., suppress leakage of a signal from one microwave transmission line to another.

In the sixth embodiment, based on the configuration of the first embodiment, the ground lines forming microwave transmission lines are divided into portions associated with respective RF power amplifiers. Alternatively, the configuration of the second embodiment shown in FIG. 4, the configuration of the third embodiment shown in FIG. 5, the configuration of the fourth embodiment shown in FIG. 6, the configuration of the fifth embodiment shown in FIG. 7, or a combination of two or more of the configurations of the second through fifth embodiments, the ground lines forming microwave transmission lines may be divided into portions associated with respective RF power amplifiers.

What is claimed is:

1. An electronic device, comprising:
a plurality of RF power amplifiers for amplifying RF signals having different frequencies; and
an impedance converting circuit for receiving RF signals output from respective output terminals of the RF power amplifiers at a plurality of input terminals disposed to face the respective output terminals, and for performing impedance conversion.

2. The electronic device of claim 1, wherein a real part of an input impedance of each of the RF signals input to the input terminals of the impedance converting circuit from the output terminals of the RF power amplifiers is 1Ω or more and less then 30Ω, and
the impedance converting circuit converts the input impedance into an impedance having a real part of 30Ω or more.

3. The electronic device of claim 1, wherein means for changing at least one of an electrical length and an input impedance is connected to at least one of the input terminals of the impedance converting circuit.

4. The electronic device of claim 1, wherein at least two of lines connecting the input terminals of the impedance converting circuit and a plurality of output terminals of the impedance converting circuit associated with the respective input terminals intersect with each other, thereby making the order of arrangement of the input terminals and the order of arrangement of the output terminals differ from each other.

5. The electronic device of claim 1, wherein the impedance converting circuit includes a bias supplying circuit for supplying a DC power supply voltage necessary for operating a transistor used in at least one of the RF power amplifiers through an associated one of the output terminals of the RF power amplifiers.

6. The electronic device of claim 1, wherein the impedance converting circuit includes one of a coupler for detecting an RF signal passing through at least one of the output terminals for outputting RF signals subjected to impedance conversion and an additional terminal for outputting the detected signal.

7. The electronic device of claim 5, wherein the impedance converting circuit includes, between a DC-power-supply-voltage supplying terminal of the bias supplying circuit and a ground, a protection circuit for bypassing a surge component so as to protect a transistor used in one of the RF power amplifiers.

8. The electronic device of claim 1, wherein at least one of the output terminals of the RF power amplifiers is output terminals of a balanced circuit,
the output terminals are composed of a pair of terminals,
the impedance converting circuit includes input terminals of another balanced circuit, and
the input terminals are composed of a pair of terminals disposed to face the output terminals of the balanced circuit.

9. The electronic device of claim 1, wherein the impedance converting circuit includes a microwave transmission line in which a signal line and a ground line are placed in a dielectric substrate, as means for converting an impedance.

10. The electronic device of claim 5, wherein the impedance converting circuit includes a microwave transmission line in which a signal line and a ground line are placed in a dielectric substrate, as means for forming the bias supplying circuit.

11. The electronic device of claim 9, wherein the ground line forming the microwave transmission line is divided into portions associated with the respective RF power amplifiers.

12. The electronic device of claim 10, wherein the ground line forming the microwave transmission line is divided into portions associated with the respective RF power amplifiers.
